(19) United States
(12) Patent Application Publication
(10) Pub. No.: US 2013/0082332 A1
(43) Pub. Date: Apr. 4, 2013

(54) METHOD FOR FORMING N-TYPE AND P-TYPE METAL-OXIDE-SEMICONDUCTOR GATES SEPARATELY

(71) Applicants: Jinping Liu, Hopewell Junction, NY (US); Min Dai, Mahwah, NJ (US); Ju Youn Kim, Fishkill, NY (US); Michael P. Chudzik, Ridgefield, CT (US); Jedon Kim, Fishkill, NY (US); Sungkee Han, Gyeonggi-do (KR)

(72) Inventors: Jinping Liu, Hopewell Junction, NY (US); Min Dai, Mahwah, NJ (US); Ju Youn Kim, Fishkill, NY (US); Michael P. Chudzik, Ridgefield, CT (US); Jedon Kim, Fishkill, NY (US); Sungkee Han, Gyeonggi-do (KR)

(73) Assignees: GLOBALFOUNDRIES Singapore Pte. Ltd., Singapore (SG); Samsung Electronics Co., Ltd., Suwon-si (KR); International Business Machines Corporation, Armonk, NY (US)

(21) Appl. No.: 13/249,643

(22) Filed: Sep. 30, 2011

(51) Int. Cl. H01L 27/092; H01L 21/28

(52) U.S. Cl. 257/369; 438/592; 257/E27.062; 257/E21.19

(57) ABSTRACT

Semiconductor devices with replacement gate electrodes are formed with different materials in the work function layers. Embodiments include forming first and second removable gates on a substrate, forming first and second pairs of spacers on opposite sides of the first and second removable gates, respectively, forming a hardmask layer over the second removable gate, removing the first removable gate, forming a first cavity between the first pair of spacers, forming a first work function material in the first cavity, removing the hardmask layer and the second removable gate, forming a second cavity between the second pair of spacers, and forming a second work function material, different from the first work function material, in the second cavity.

### TECHNICAL FIELD

The present disclosure relates to a method of fabricating semiconductor devices with metal gates and the resulting devices. The present disclosure is particularly applicable to fabricating semiconductor devices with NMOS and PMOS gates made from two different work function materials.

### BACKGROUND

The integration of hundreds of millions of circuit elements, such as transistors, on a single integrated circuit necessitates further dramatic scaling down or micro-miniaturization of the physical dimensions of circuit elements, including interconnection structures. Micro-miniaturization has engendered a dramatic increase in transistor engineering complexity, such as the inclusion of lightly doped drain structures, multiple implants for source/drain regions, silicidation of gates and source/drains, and multiple sidewall spacers, for example.

The drive for high performance requires high speed operation of microelectronic components requiring high drive currents in addition to low leakage (i.e., low off-state current) to reduce power consumption. Typically, the structural and doping parameters tending to provide a desired increase in drive current adversely impact leakage current.

Metal gate electrodes have evolved for improving the drive current by reducing polysilicon depletion. However, simply replacing polysilicon gate electrodes with metal gate electrodes may engender issues in forming the metal gate electrode prior to high temperature annealing to activate the source/drain implants, as at a temperature in excess of 900° C. This fabrication technique may degrade the metal gate electrode or cause interaction with the gate dielectric, thereby adversely impacting transistor performance.

Replacement gate techniques have been developed to address problems attendant upon substituting metal gate electrodes for polysilicon gate electrodes. For example, a polysilicon gate is used during initial processing until high temperature annealing to activate source/drain implants has been implemented. Subsequently, the polysilicon is removed and replaced with a metal gate. However, additional issues arise with forming replacement metal gates.

Historically, semiconductor manufacturers have used a single process to form n-type and p-type metal-oxide-semiconductor (N/PMOS) replacement gates at the same time. Because of the different work function control requirements for NMOS gates and PMOS gates, two different work function materials, one for NMOS gates and one for PMOS gates are needed. However, these two different materials within the same gate tend to interact with each other, making work function targeting difficult. Additionally, the process of forming NMOS work function material in the PMOS gate causes fill problems.

A need therefore exists for methodology enabling the fabrication of semiconductor devices including NMOS and PMOS gates made with different work function materials, made during separate and distinct processes and the resulting devices.

### SUMMARY

An aspect of the present disclosure is an efficient method of fabricating a semiconductor device with replacement metal gate electrodes having NMOS and PMOS gates made separately with different work function materials.

Another aspect of the present disclosure is a semiconductor device including NMOS and PMOS gates made with different work function materials.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of fabricating a semiconductor device, the method including: forming a first removable gate and a second removable gate on a substrate; forming a first pair of spacers and a second pair of spacers on opposite sides of the first removable gate and the second removable gate, respectively; forming a hardmask layer over the second removable gate; removing the first removable gate, forming a first cavity between the first pair of spacers; forming a first work function material between the first pair of spacers; removing the hardmask layer and the second removable gate, forming a second cavity between the second pair of spacers; and forming a second work function material, different from the first work function material, in the second cavity.

Aspects of the present disclosure include forming the hardmask layer of polysilicon, amorphous silicon or a combination thereof. Further aspects include forming a first dielectric layer in the first cavity prior to forming the first work function material, and forming a second dielectric layer in the second cavity prior to forming the second work function material. Another aspect includes forming a first metal fill layer over the first work function material, and forming a second metal fill layer over the second work function material. Additional aspects include forming the hardmask layer over the second removable gate by: forming a hardmask material over the first and second removable gates, patterning a photoresist over the hardmask material with an opening over the first removable gate, and removing the hardmask material over the first removable gate through the opening; and removing the hardmask layer over the second removable gate by: patterning, after forming the first work function material, a mask with an opening over the second removable gate and the hardmask over the second removable gate, and removing the hardmask layer through the opening.

Another aspect of the present disclosure includes a method of fabricating a semiconductor device, the method including: forming two removable gates on a substrate, each having a pair of spacers on opposite sides thereof; removing the two removable gates, to form two gate trenches; forming a hardmask layer over the two gate trenches; removing the hardmask layer over a first gate trench of the two gate trenches; forming a first work function layer over the first gate trench; removing the hardmask layer over a second gate trench of the two gate trenches; forming a second work function layer, different from the first work function layer, over the second gate trench.

Aspects include forming the hardmask layer of polysilicon, amorphous silicon, or a combination thereof. Another aspect includes conformally forming a dielectric layer in the two gate trenches prior to depositing the hardmask layer. An additional aspect includes forming a capping layer over the dielectric layer prior to depositing the hardmask layer. Additional aspects include forming a threshold modulation layer over the dielectric material of the second gate trench, and forming a capping layer over the threshold modulation layer of the second gate trench prior to forming the second work function layer. Another aspect includes forming a seal layer over the capping layer prior to forming the second work function layer. Further aspects include forming a capping layer over the dielectric layer of the second gate trench after removing the hardmask layer over the second gate trench, and forming a seal layer over the capping layer. Another aspect includes filling a remainder of the first gate trench with a first metal fill layer subsequent to forming the first work function layer, and filling a remainder of the second gate trench with a second metal fill layer subsequent to forming the second work function layer.

Another aspect of the present disclosure is a semiconductor device including: a substrate; a p-type gate on the substrate, the p-type gate including a first work function layer; an n-type gate on the substrate, the n-type gate including a second work function layer different from the first work function layer; and spacers on opposite side surfaces of each of the p-type gate and the n-type gate.

Aspects include a dielectric layer under the first work function layer and under the second work function layer, for the p-type gate and the n-type gate, respectively. Another aspect includes a capping layer between the dielectric layer and each of the first and second work function layers, for the p-type gate and the n-type gate, respectively. Further aspects include an additional dielectric layer between the dielectric layer and the second work function layer for the n-type gate. Another aspect includes wherein the dielectric layer comprises hafnium oxide and the additional dielectric layer includes lanthanum oxide. An additional aspect includes a titanium nitride capping layer on the additional dielectric for the n-type gate. Another aspect includes a seal layer between the capping layer and the second work function layer for the n-type gate. Additional aspects include a first metal fill layer on the first work function layer, and a second metal fill layer on the second work function layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1 through 12 schematically illustrate replacement metal gate process steps, in accordance with an exemplary embodiment;

FIGS. 13A through 23 schematically illustrate replacement metal gate process steps, in accordance with another exemplary embodiment;

FIG. 24 schematically illustrates an alternative to the step illustrated in FIG. 23, in accordance with another exemplary embodiment; and

FIGS. 25A through 25D schematically illustrate four different types of replacement metal gate stacks, according to exemplary embodiments.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of N-type metal-oxide-semiconductor equivalent oxide thickness caused by gate leakage (Toxgl), work function tuning problems caused by interactions between work function materials and gap fill problems associated with replacement metal gate processing. In accordance with embodiments of the present disclosure, NMOS and PMOS gates are formed separately allowing for better tuning of the respective work function materials and preventing PMOS gap fill issues. In addition, NMOS gates are formed with the addition of barrier or capping layers to improve NMOS Toxgl issues.

Methodology in accordance with embodiments of the present disclosure includes forming two removable gates on a substrate, each of the two removable gates having a pair of spacers on opposite sides. The two removable gates are removed from between the spacers to form two trenches, which are filled with a hardmask layer made of polysilicon and/or amorphous silicon. The trenches may be lined with a gate dielectric layer and a capping layer before they are filled with the hardmask layer. The hardmask layer is removed over one of the two trenches, for example the one corresponding to the PMOS gate. If a gate dielectric layer was not previously formed in the trenches, a gate dielectric layer is formed to line the sides and bottom of the exposed PMOS trench. Subsequently, a PMOS work function layer including, for example, titanium nitride (TiN), an optional barrier layer (e.g., TiN), and a seal (or wetting) layer of, for example, titanium, are sequentially formed in the trench, which is then filled with a metal fill of, for example, aluminum or tungsten.

The hardmask over the other trench is then removed. If a gate dielectric layer was not previously formed in the trench, a gate dielectric layer is formed to line the sides and bottom of the trench. This gate dielectric layer may be of the same material as the gate material discussed above, or may be a different gate material. Further, an additional gate dielectric layer may be formed above the first gate dielectric layer of a different material, for example lanthanum oxide. The additional gate dielectric layer may be added, for example, to help modulate the threshold voltage of the NMOS gate. A capping layer, for example TiN, and an additional seal (or wetting) layer of, for example, titanium are formed over the gate dielectric layer(s). Subsequently, a NMOS work function layer including, for example, titanium aluminide, an optional barrier layer (e.g., TiN) and a seal (or wetting) layer of, for example, titanium are sequentially formed on the seal (or wetting) layer followed by a metal fill of, for example, aluminum or tungsten. However, depending on the size of the gates, forming the work function layers to the desired thicknesses may completely fill the gates such that the addition of other layers, such as the metal layers, are unnecessary.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

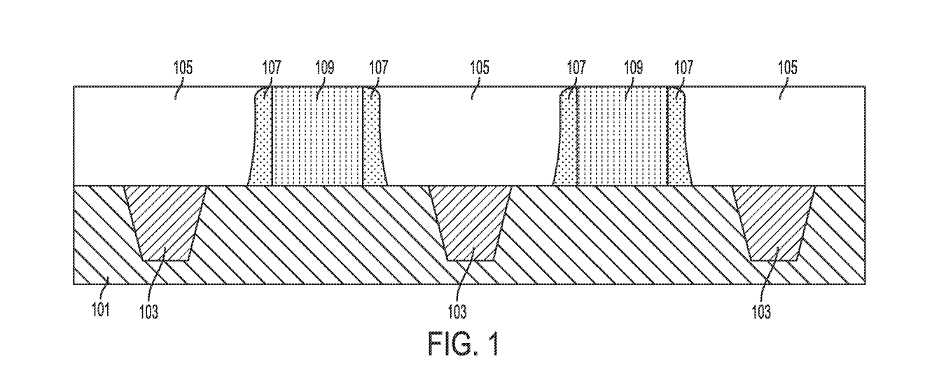

Adverting to FIG. 1, a method for forming a semiconductor, in accordance with an exemplary embodiment, begins with a conventional formation of removable gate electrodes. For example, removable gate electrodes 109 made from, for example, polysilicon (poly-Si) or amorphous silicon (α-Si), are formed between pairs of spacers 107 on a silicon substrate 101. Embedded within substrate 101, and electrically isolating adjacent removable gate electrodes 109 from each other, are shallow trench isolation (STI) structures 103. Surrounding the spacers 107 and removable gate electrodes 109 is an interlayer dielectric (ILD) 105, typically silicon dioxide (SiO₂).

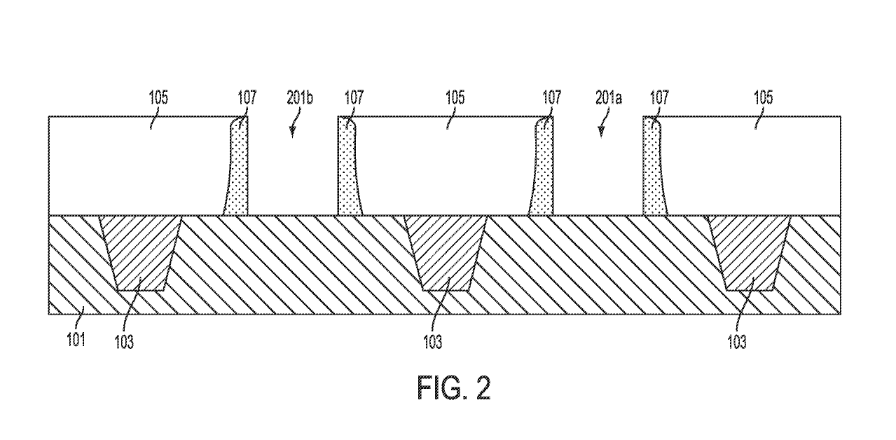

As illustrated in FIG. 2, removable gate electrodes 109 are removed leaving trenches 201a and 201b between spacers 107. The removable gate electrodes 109 may be removed using any conventional removal process, such as wet chemistry processes and/or a combination of dry and wet chemistry processes.

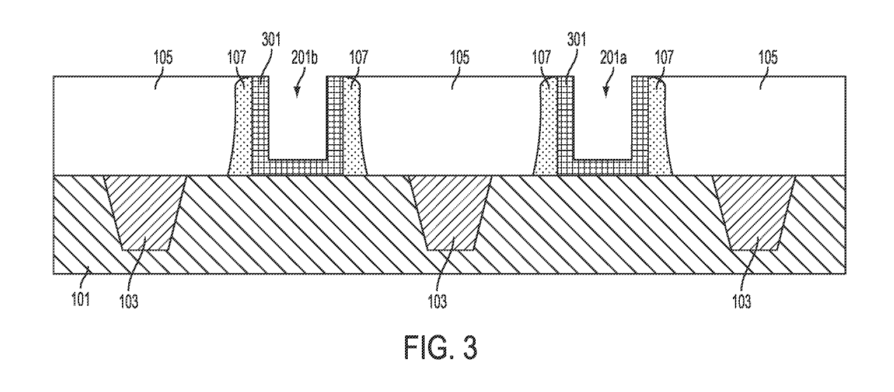

Next, a gate dielectric layer 301 is conformally formed over ILD 105 and in trenches 201a and 201b, lining both sides and the bottom of each trench. The gate dielectric layer 301 can be a high-k dielectric, for example having a dielectric constant of about 25 or greater, such as hafnium oxide, hafnium silicate, zirconium silicate, zirconium dioxide, silicon dioxide, etc. After a post deposition anneal, a first, thin metal layer (not shown for illustrative convenience) (e.g., titanium nitride (TiN)) may be deposited over the gate dielectric layer 301 as a capping layer. The capping layer may be formed to a thickness of around 20 Å (for example 5 Å to 50 Å). Gate dielectric layer 301 and any capping layer are removed from above ILD 105 by any conventional removal processing, such as polishing, e.g., chemical mechanical polishing (CMP). Thus, the result is a gate dielectric layer 301 and a thin metal layer (not shown for illustrative convenience) lining both sides and the bottom of each of trenches 201a and 201b, as illustrated in FIG. 3.

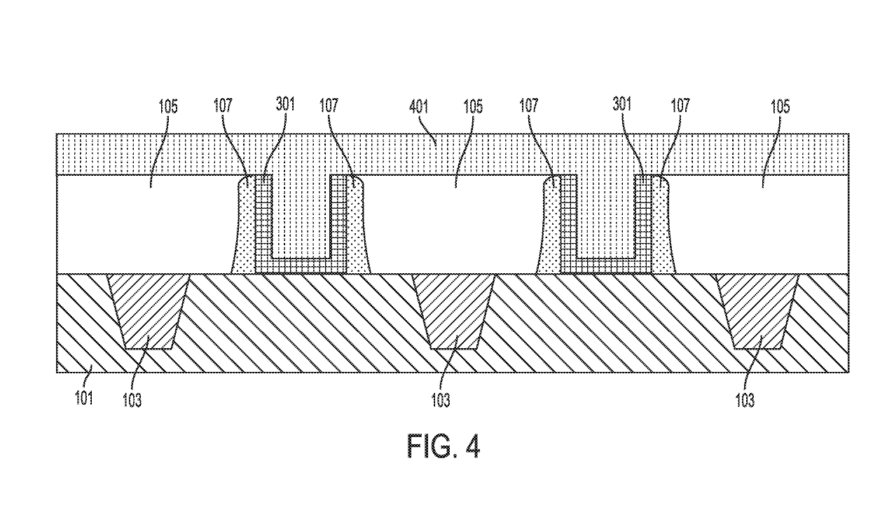

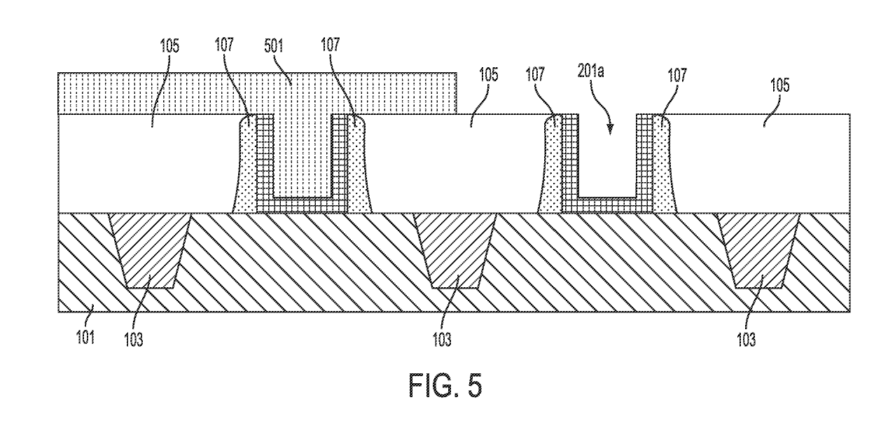

Adverting to FIG. 4, a hardmask layer 401 is then deposited over ILD 105, the spacers 107 and filling trenches 201a and 201b. The hardmask layer 401 may be formed of, for example, poly-Si or α-Si. Subsequently, a photo resist material (not shown for illustrative convenience) is patterned over hardmask layer 401 with an opening over one of the two trenches 201a and 201b. Hardmask layer 401 is then removed from the one trench, leaving a partial hardmask layer 501 covering the other of the two trenches 201a and 201b. By way of example, the partial hardmask layer 501 remains covering the trench 201b and is removed from the trench 201a, as illustrated in FIG. 5.

The partial hardmask layer 501 may remain over the trench that will correspond to either the NMOS gate or the PMOS gate. For purposes of explanation, the partial hardmask layer 501 remains over the trench 201b corresponding to the NMOS gate with the trench 201a corresponding to the PMOS gate exposed.

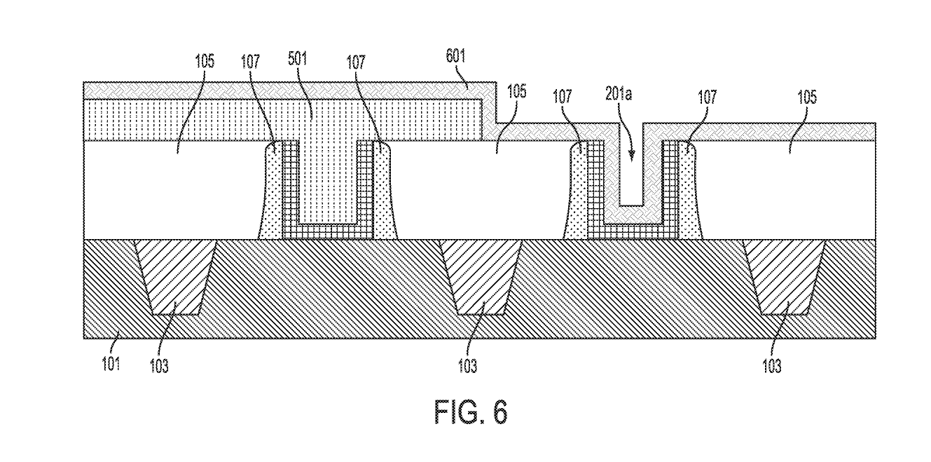

As illustrated in FIG. 6, a PMOS work function layer 601 is deposited over the partial hardmask layer 501, over ILD 105, and lining the inner sidewalls and bottom of the trench 201a covering the gate dielectric layer 301. The PMOS work function layer 601 may be formed of any suitable PMOS work function material, such as titanium nitride. PMOS work function layer 601 may be deposited to a thickness of about 50 Å (for example 20 Å to 150 Å). A barrier layer (not shown for illustrative convenience) may optionally be deposited over the PMOS work function layer 601. The barrier layer may be formed of, for example, titanium nitride (TiN). Further, a seal (or wetting) layer (not shown for illustrative convenience) of, for example, titanium may be formed over the barrier layer.

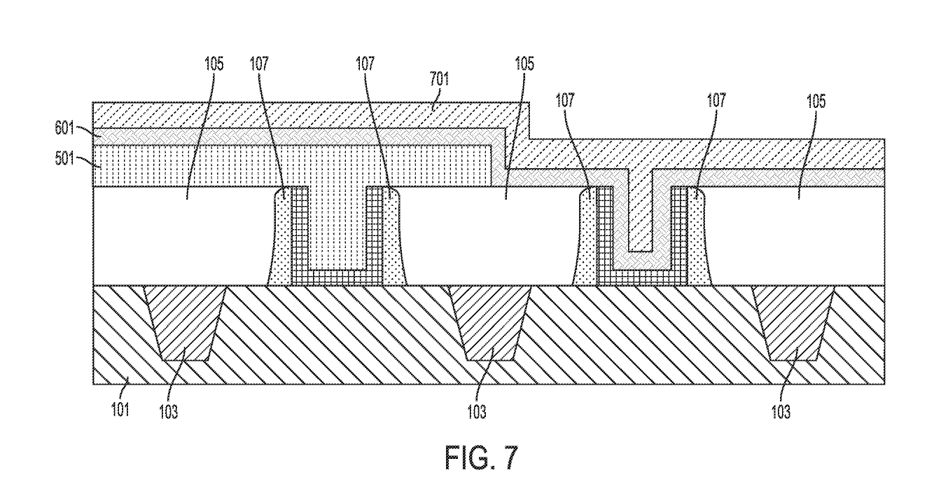

Subsequently, as illustrated in FIG. 7, a metal layer 701 is deposited over the PMOS work function layer 601 to fill the trench 201a. The metal layer 701 may be formed of, for example, aluminum or tungsten. The metal layer 701 may be deposited by physical vapor deposition (PVD) or chemical vapor deposition (CVD) followed by PVD. However, depending on the size of the trench 201a and the thickness of the layers, the metal layer 701 may be unnecessary as the trench 201a may already be filled by the other layers.

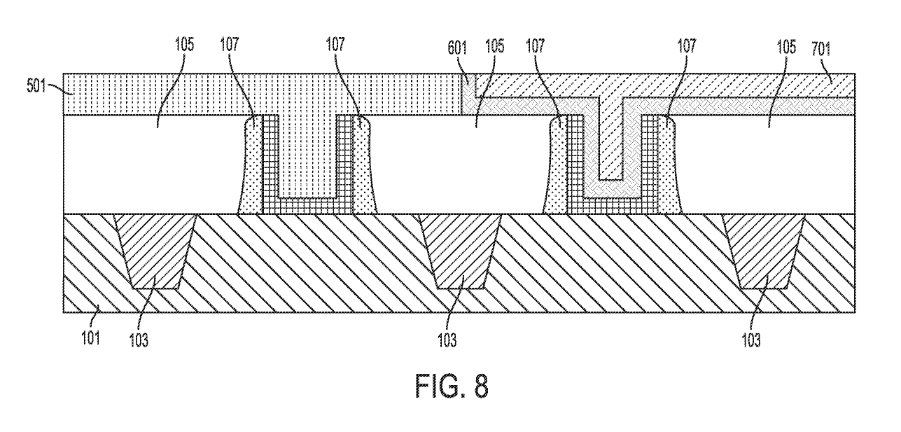

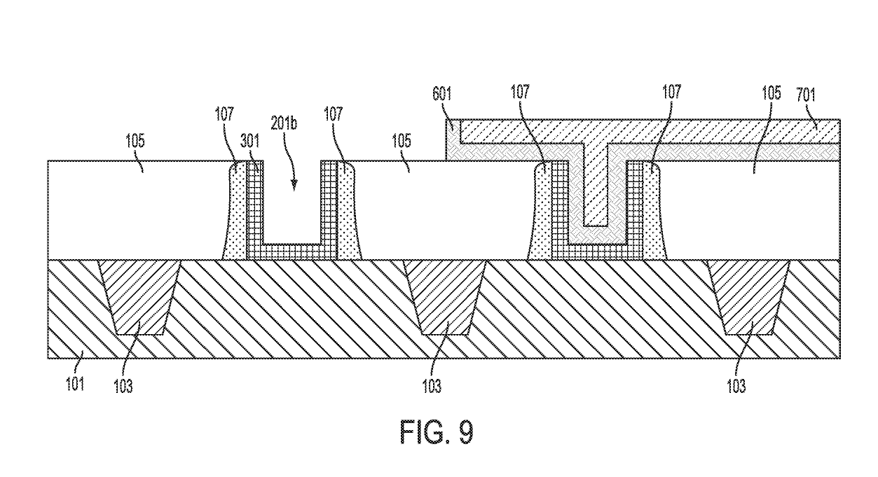

The metal layer 701, the PMOS work function layer 601, and any seal layer and/or barrier layer, over trench 201b, are polished down to the level of the partial hardmask layer 501, as illustrated in FIG. 8. Next, the partial hardmask layer 501 is removed from over the trench 201b, as illustrated in FIG. 9, for example by wet chemistry and/or a combination of dry and wet chemistries. The removal of the partial hardmask layer 501 exposes the trench 201b for forming the NMOS gate.

If no capping layer was previously formed over gate dielectric 301, a thin metal layer (not shown for illustrative convenience) (e.g., TiN) may be deposited over the gate dielectric layer 301 in trench 201b. Prior to depositing the thin metal layer, an additional gate dielectric layer (not shown for illustrative convenience) may be deposited over gate dielectric layer 301 in trench 201b. The additional gate dielectric layer can be a high-k dielectric, for example having a dielectric constant of about 25 or greater, such as hafnium oxide, hafnium silicate, zirconium silicate, zirconium dioxide, silicon dioxide, lanthanum oxide, etc. The additional gate dielectric layer may be added, for example, to help modulate the threshold voltage of the NMOS gate. Further, a seal (or wetting) layer (not shown for illustrative convenience) of, for example, titanium may be formed over the capping layer.

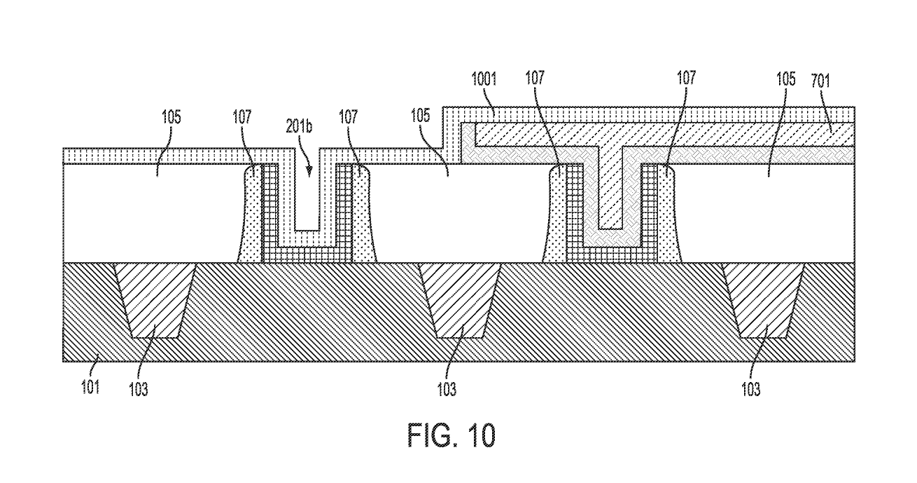

Next, as illustrated in FIG. 10, a NMOS work function layer 1001 is conformally deposited over ILD 105, in trench 201b, and over the previously deposited PMOS work function layer 601 and metal layer 701. NMOS work function layer 1001 may be formed of any suitable NMOS work function material, such as titanium aluminide (TiAl). NMOS work function layer 1001 may be deposited to a thickness of around 150 Å (for example 25 Å to 200 Å). A barrier layer (not shown for illustrative convenience) may optionally be deposited over the NMOS work function layer 1001. The barrier layer may be formed of, for example, titanium nitride (TiN). Further, a seal (or wetting) layer (not shown for illustrative convenience) of, for example, titanium may be formed over the barrier layer.

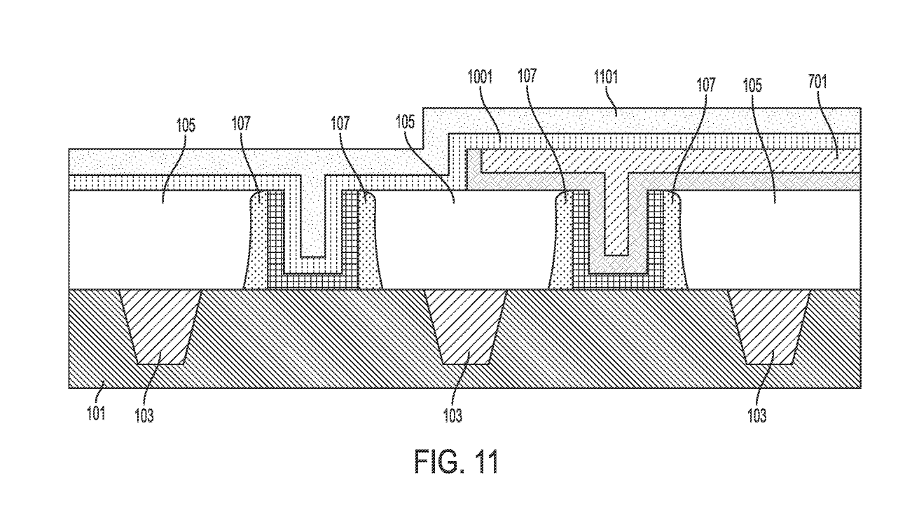

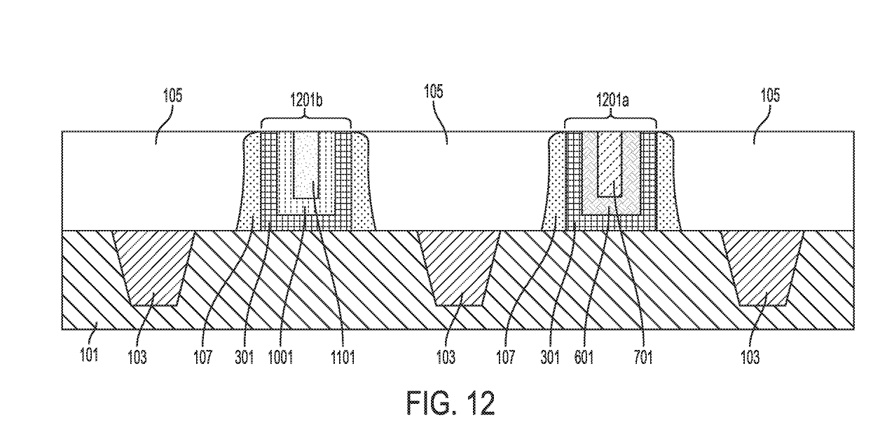

Subsequently, as illustrated in FIG. 11, a metal layer 1101 is deposited over the NMOS work function layer 1001 to fill the trench 201b. Metal layer 1101 may be formed of, for example, aluminum or tungsten and may be deposited by PVD or CVD followed by PVD. Next, metal layer 1101, any NMOS seal layer and/or barrier layer formed in the NMOS gate, and the NMOS work function layer 1001, in addition to the metal layer 701, any PMOS seal layer and/or barrier layer formed in the PMOS gate, and PMOS work function layer 601, are removed down to ILD 105 by polishing, as illustrated in FIG. 12. As a result, NMOS gate 1201b may be formed from one work function material and PMOS gate 1201a may be formed of another, different work function material.

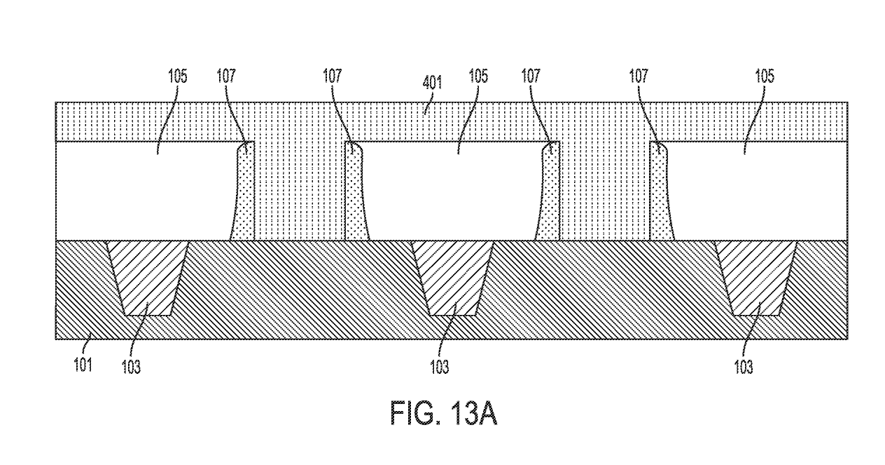

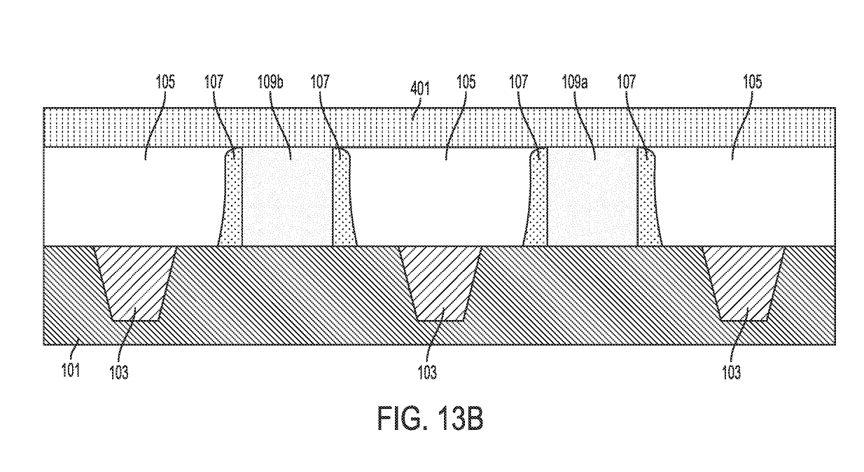

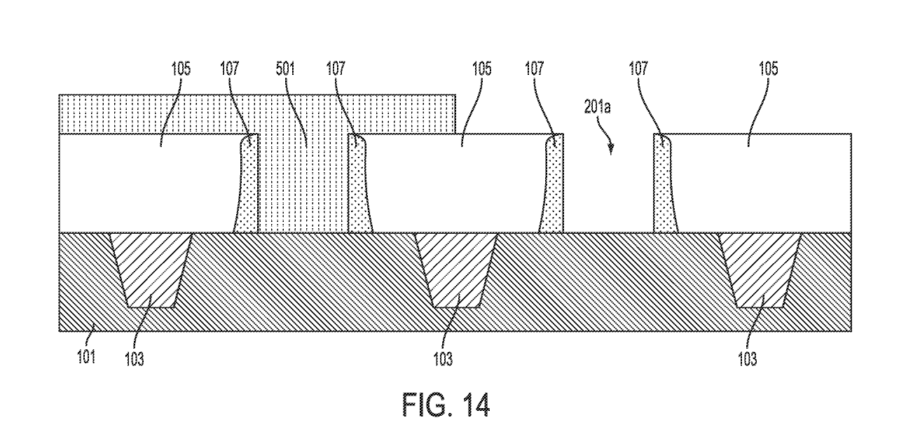

In accordance with another exemplary embodiment, all layers of one gate may be formed prior to forming layers of the other gate, such that the PMOS gate and the NMOS gate are formed completely independently. For example, after removal of the removable gate electrodes 109 forming the two trenches 201a and 201b, as discussed above with respect to FIG. 2, rather than depositing gate dielectric 301, hardmask layer 401 may be deposited over ILD 105, the spacers 107, and the trenches 201a and 201b, as illustrated in FIG. 13A. Alternatively, instead of removing removable gate electrodes 109a and 109b, the hardmask layer 401 may be deposited over the ILD 105 and removable gate electrodes 109a and 109b, as illustrated in FIG. 13B. (For illustrative convenience, FIGS. 14 through 18 only show the first alternative, with gate electrode 109b having been removed, as in FIG. 13A.)

Subsequently, as discussed above, a photo resist material (not shown for illustrative convenience) is patterned over hardmask layer 401 to enable the removal of the hardmask layer 401 from over one of the two trenches 201a and 201b (or alternatively to enable removal the hardmask layer 401 from over one of the two removable gate electrodes 109a and 109b as well as the exposed gate electrode, if the removable gate electrodes 109a and 109b were not previously removed). Upon removal of the hardmask layer 401 over one of the two trenches 201a and 201b, a partial hardmask layer 501 remains covering the other of the two trenches 201a and 201b (or alternatively covering the other of the two removable gate electrodes 109a and 109b). By way of example, the partial hardmask layer 501 remains covering the trench 201b (or alternatively the removable gate electrode 109b), which will be the NMOS gate, and is removed from the trench 201a (or alternatively from and with removable gate electrode 109a), which will be the PMOS gate, as illustrated in FIG. 14.

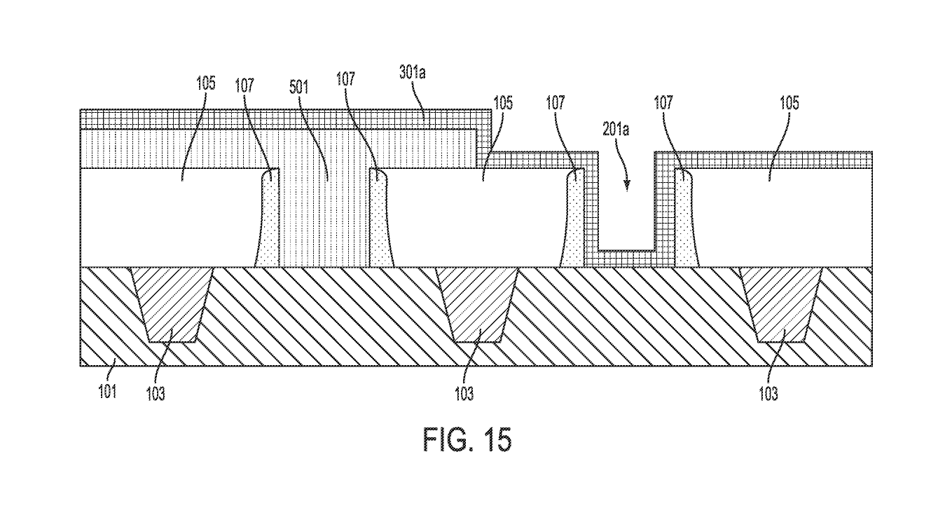

A gate dielectric layer 301a is then conformally formed over ILD 105 and lining the sides and bottom of trench 201a, as illustrated in FIG. 15. As discussed above, the gate dielectric layer 301a can be a high-k dielectric, for example having a dielectric constant of about 25 or greater, such as hafnium oxide, hafnium silicate, zirconium silicate, zirconium dioxide, silicon dioxide, etc., or a combination thereof, and may include an aluminum oxide layer under the high-k dielectric. Additionally, a thin metal layer (not shown for illustrative convenience) (e.g., TiN) may optionally be deposited over the gate dielectric layer 301a as a capping layer.

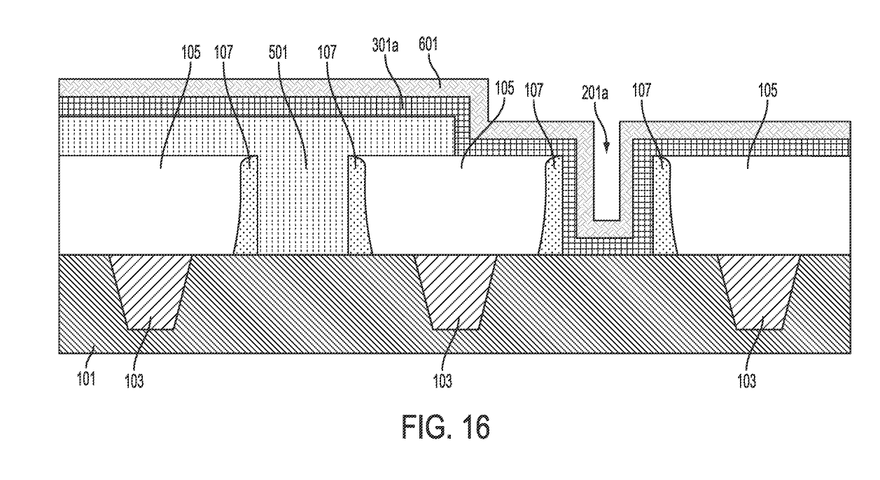

Adverting to FIG. 16, a PMOS work function layer 601 is deposited over the gate dielectric layer 301a. The PMOS work function layer 601 may be formed of any suitable PMOS work function material, such as TiN. PMOS work function layer 601 may be deposited to a thickness of about 50 Å (for example 20 Å to 150 Å). A barrier layer (not shown for illustrative convenience) may be deposited over the PMOS work function layer 601. The barrier layer may be formed of, for example, TiN. Further, a seal (or wetting) layer (not shown for illustrative convenience) of, for example, titanium may be formed over the barrier layer.

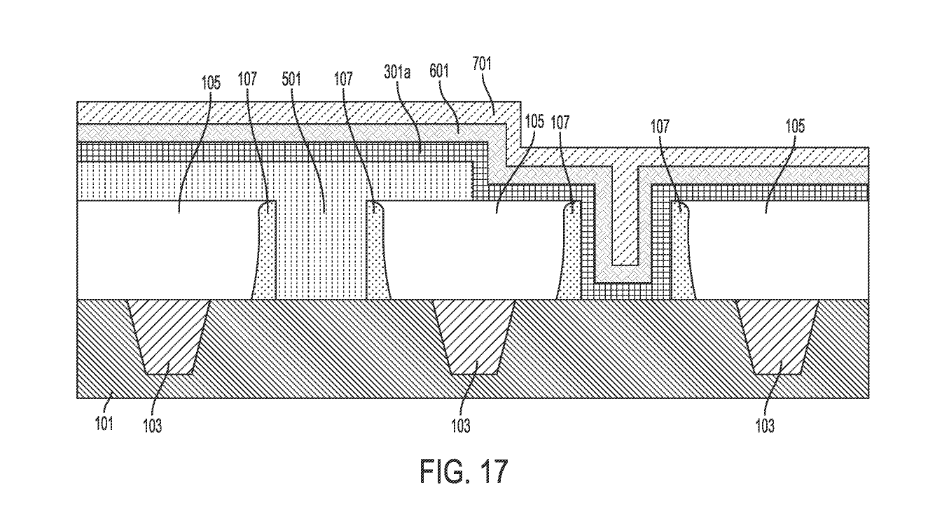

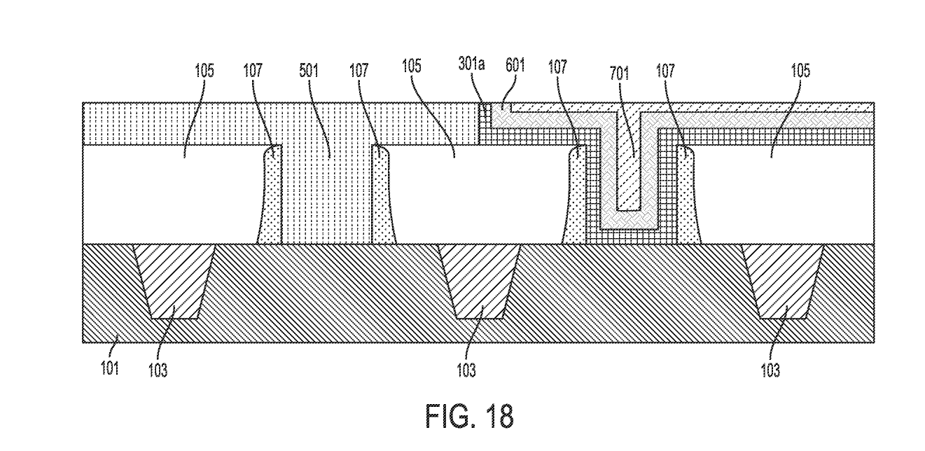

A metal layer 701 is then deposited over the PMOS work function layer 601, as illustrated in FIG. 17. The metal layer 701 may be formed of, for example, aluminum or tungsten and may be deposited by PVD or CVD followed by PVD. After depositing the metal layer 701, the metal layer 701, any seal layer and/or barrier layer, PMOS work function layer 601, and the gate dielectric layer 301a are polished down to the level of the partial hardmask layer 501, as illustrated in FIG. 18.

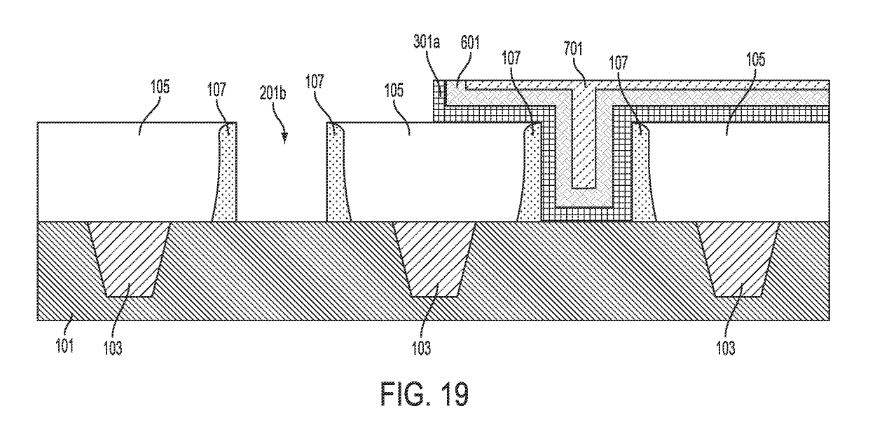

Subsequently, the partial hardmask layer 501 (or alternatively the partial hardmask 501 and the remaining removable gate electrode 109b, if the remaining removable gate electrode 109b was not removed prior to forming the hardmask layer 401) is removed via wet chemistry and/or a combination of dry and wet chemistries, as illustrated in FIG. 19. The removal of the partial hardmask layer 501 (or alternatively the partial hardmask 501 and the removable gate electrode 109b) exposes the trench 201b for forming the NMOS gate.

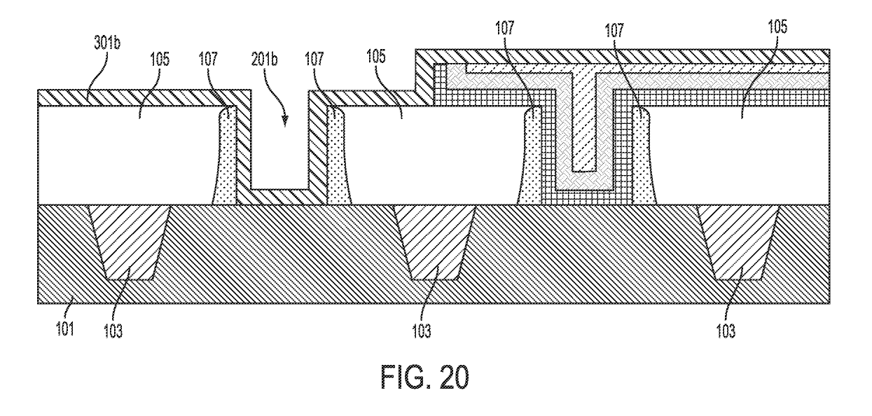

After removing the partial hardmask layer 501, a gate dielectric layer 301b is formed over ILD 105 and lining the sides and bottom of the trench 201b, as illustrated in FIG. 20. As discussed above, the gate dielectric layer 301b can be a high-k dielectric, for example having a dielectric constant of about 25 or greater, such as hafnium oxide, hafnium silicate, zirconium silicate, zirconium dioxide, silicon dioxide, etc. Layer 301b may also include a layer of lanthanum oxide, formed to a thickness about 2 Å (for example 1 Å to 5 Å) under the high-k dielectric layer, for example to help modulate the threshold voltage of the NMOS gate. Because the gate dielectric layer 301b is deposited at a different step than the gate dielectric layer 301a, the gate dielectric layers 301a and 301b can be different materials. Additionally, a thin metal layer (not shown for illustrative convenience) (e.g., TiN) may optionally be deposited as a capping layer over the gate dielectric layer 301b, particularly if no capping layer is formed over gate dielectric 301a. The capping layer may have a thickness of about 20 Å (for example 10 Å to 30 Å). Above the other capping layer, another seal (or wetting) layer (not shown for illustrative convenience) may be formed of, for example, titanium, to a thickness about 40 Å (for example 5 Å to 250 Å).

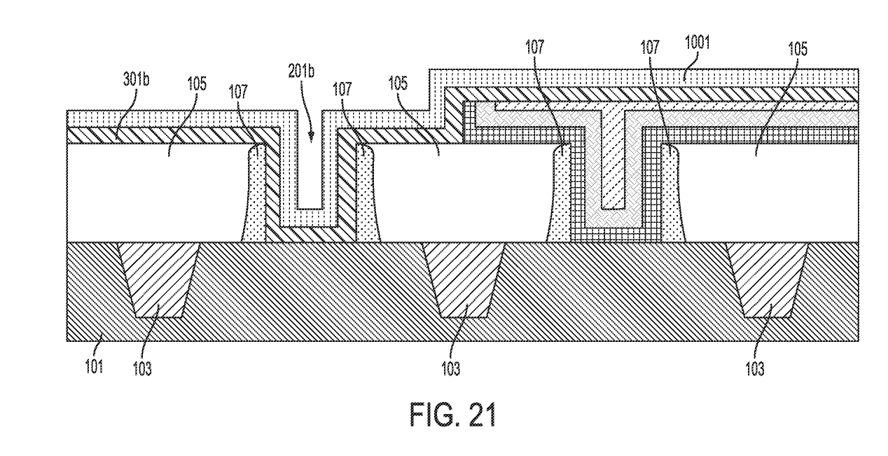

Adverting to FIG. 21, an NMOS work function layer 1001 is deposited over the gate dielectric layer 301b. The NMOS work function layer 1001 may be formed of any suitable NMOS work function material, such as TiAl. NMOS work function layer 1001 is deposited to a thickness of around 150 Å (for example 20 Å to 200 Å). A barrier layer of, for example, TiN (not shown for illustrative convenience), may be deposited over the NMOS work function layer 1001. Further, a seal (or wetting) layer (not shown for illustrative convenience) of, for example, titanium may be formed over the barrier layer.

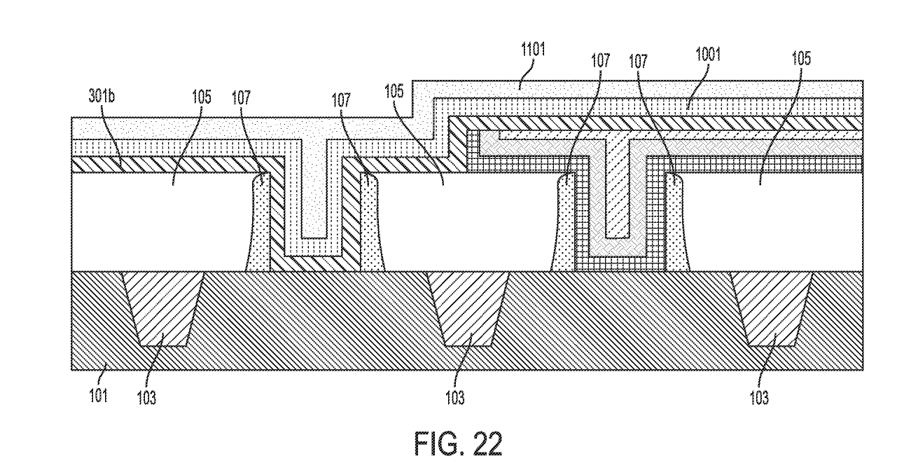

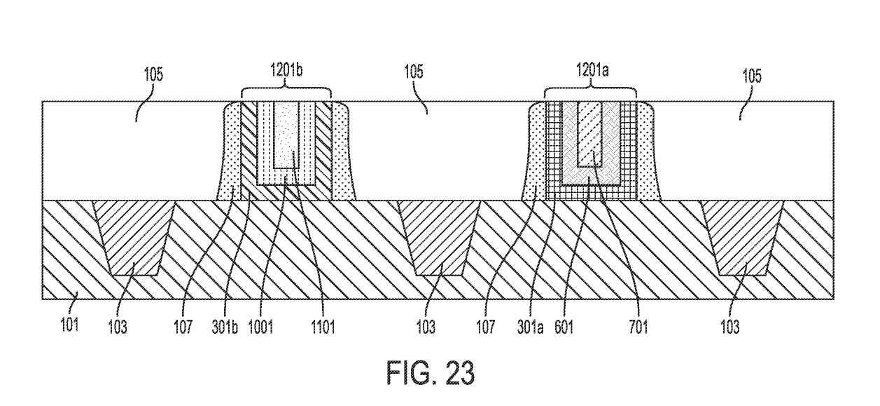

Next, a metal layer 1101 is deposited over the NMOS work function layer 1001, as illustrated in FIG. 22. The metal layer 1101 may be formed of, for example, aluminum or tungsten and may be deposited by PVD or CVD followed by PVD. After depositing the metal layer 1101, the metal layer 1101, any NMOS seal layer and/or barrier layer, the NMOS work function layer 1001, and the gate dielectric layer 301b, in addition to the metal layer 701, any PMOS seal layer and/or barrier layer, the PMOS work function layer 601, and gate dielectric layer 301a, are removed down to ILD 105 by polishing, as illustrated in FIG. 23. As a result, a NMOS gate 1201b may be formed of one work function material and gate dielectric layer, and a PMOS gate 1201a may be formed of a different work function material and a different gate dielectric layer.

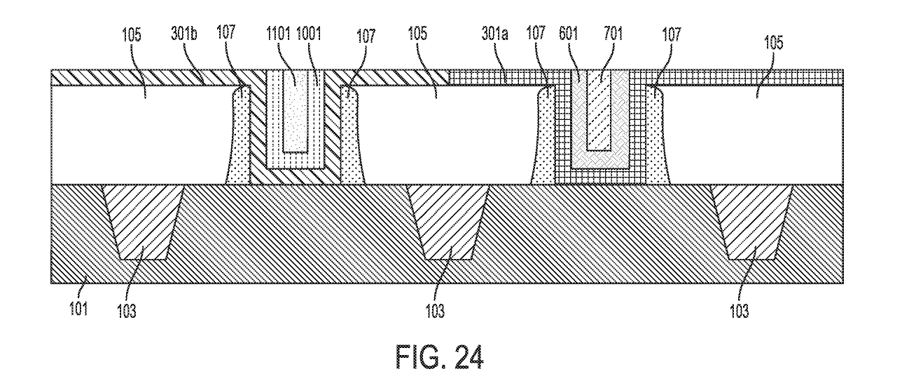

In an alternative embodiment, the metal layer 1101, any NMOS seal layer and/or barrier layer, and the NMOS work function layer 1001, as well as the gate dielectric layer 301b, metal layer 701, any PMOS seal layer and/or barrier layer, PMOS work function layer 601, and gate dielectric layer 301a over trench 201a, are removed down to the height of the gate dielectric layers 301a and 301b directly above ILD 105. The resulting device includes gate dielectric layers 301a and 301b substantially coplanar above ILD 105, as illustrated in FIG. 24.

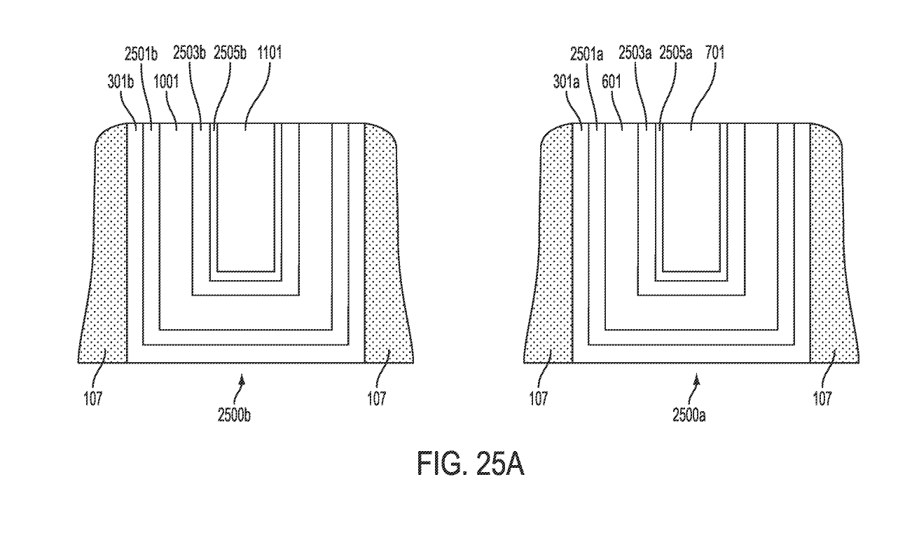

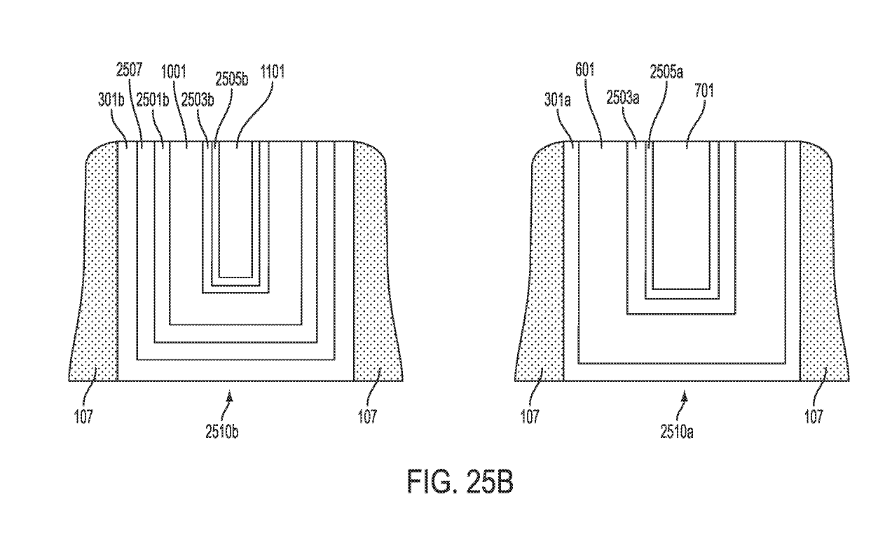

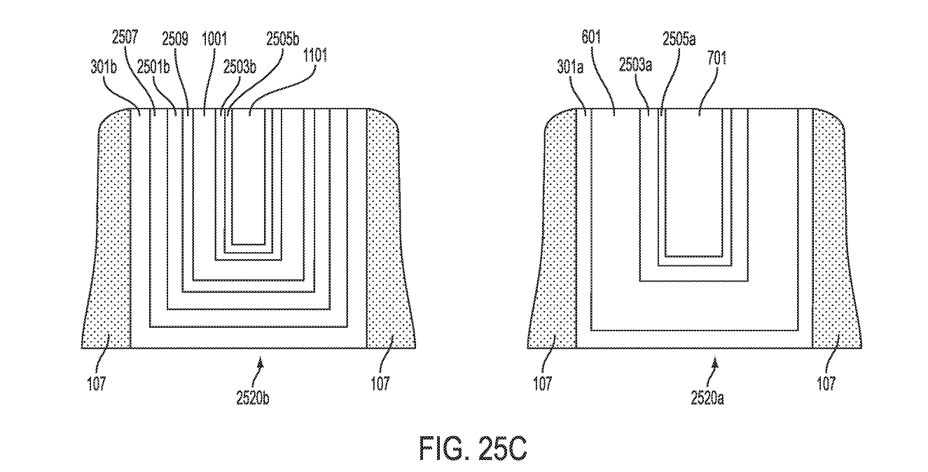

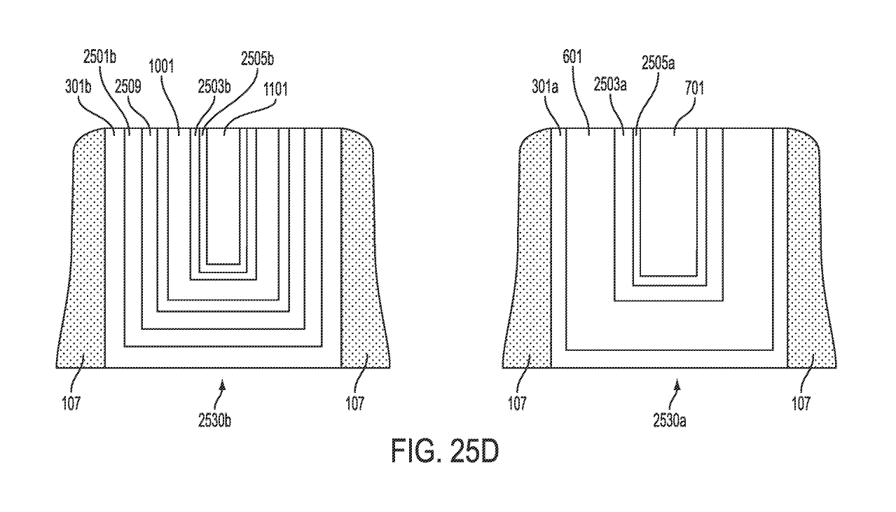

FIGS. 25A through 25D illustrate four different exemplary replacement metal gate pairs formed by the processes disclosed herein. FIG. 25A illustrates a PMOS replacement metal gate 2500a and a NMOS replacement metal gate 2500b each between spacers 107. The gates 2500a and 2500b include gate dielectric layers 301a and 301b, respectively. As discussed above, the gate dielectric layers 301a and 301b may be made of the same or different materials. The gates 2500a and 2500b also include capping layers 2501a and 2501b, respectively. The capping layers 2501a and 250b may have a thickness of around 20 Å (for example 5 Å to 50 Å). The PMOS replacement metal gate 2500a includes a PMOS work function layer 601, and the NMOS replacement metal gate 2500b includes a NMOS work function layer 1001. As discussed above, the PMOS work function layer 601 and the NMOS work function layer 1001 may be made of different work function materials and can have thicknesses of greater than 50 Å (for example 20 Å to 150 Å) and greater than 150 Å (for example 20 Å to 200 Å), respectively. Gates 2500a and 2500b may include barrier layers 2503a and 2503b, respectively, of, for example, TiN. The gates 2500a and 2500b may also include seal (or wetting) layers 2505a and 2505b, respectively, of, for example, titanium. The remaining space within the gates 2500a and 2500b are filled with metal layers 701 and 1101, respectively.

FIG. 25B illustrates a PMOS replacement metal gate 2510a and an NMOS replacement metal gate 2510b. The gates 2510a and 2510b are similar to the gates 2500a and 2500b, except for the following details. The PMOS replacement metal gate 2510a lacks the capping layer 2501a over the gate dielectric layer 301a. Only the NMOS replacement metal gate 2510b has a capping layer over a gate dielectric layer. Further, in the NMOS replacement metal gate 2510b, an additional gate dielectric layer 2507 is formed between the gate dielectric layer 301b and the capping layer 250b. As discussed above, this additional gate dielectric layer 2507 is used to modulate the threshold voltage of the NMOS replacement metal gate 2510b.

FIG. 25C illustrates a PMOS replacement metal gate 2520a and an NMOS replacement metal gate 2520b. The gates 2520a and 2520b are similar to the gates 2510a and 2510b, except for the following details. In the NMOS replacement metal gate 2520b, a seal layer 2509 is formed between the capping layer 250b and the NMOS work function layer 1001.

FIG. 25D illustrates a PMOS replacement metal gate 2530a and an NMOS replacement metal gate 2530b. The gates 2530a and 2530b are similar to the gates 2520a and 2520b, except for the following details. The NMOS replacement metal gate 2530b does not include the additional gate dielectric layer 2507. However, the NMOS replacement metal gate 2530b includes the seal layer 2509 and the capping layer 250b between the NMOS work function layer 1001 and the gate dielectric layer 301b.

The embodiments of the present disclosure can achieve several technical effects, such as the ability to separately tune the work functions of the NMOS and PMOS gates, improve NMOS gate leakage and reliability, and improve the metal fill issues in the trenches during formation of the NMOS and PMOS gates. The present disclosure enjoys utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specific exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming two removable gates on a substrate, each of the two removable gates having a pair of spacers on opposite sides thereof;
removing the two removable gates, to form two gate trenches;
forming a hardmask layer over the two gate trenches;
removing the hardmask layer over a first gate trench of the two gate trenches;
forming a first work function layer over the first gate trench;
removing the hardmask layer over a second gate trench of the two gate trenches;
forming a second work function layer, different from the first work function layer, over the second gate trench.

2. The method according to claim 1, further comprising forming the hardmask layer of polysilicon, amorphous silicon, or a combination thereof.

3. The method according to claim 1, further comprising:
conformally forming a dielectric layer in the two gate trenches prior to depositing the hardmask layer.

4. The method according to claim 3, further comprising:
forming a capping layer over the dielectric layer prior to depositing the hardmask layer.

5. The method according to claim 3, further comprising:
forming a threshold modulation layer over the dielectric material of the second gate trench; and
forming a capping layer over the threshold modulation layer of the second gate trench prior to forming the second work function layer.

6. The method according to claim 5, further comprising:
forming a seal layer over the capping layer prior to forming the second work function layer.

7. The method according to claim 3, further comprising:
forming a capping layer over the dielectric layer of the second gate trench after removing the hardmask layer over the second gate trench; and
forming a seal layer over the capping layer.

8. The method according to claim 1, further comprising:
filling a remainder of the first gate trench with a first metal fill layer subsequent to forming the first work function layer; and
filling a remainder of the second gate trench with a second metal fill layer subsequent to forming the second work function layer.

9. A method comprising:
forming a first removable gate and a second removable gate on a substrate;
forming a first pair of spacers and a second pair of spacers on opposite sides of the first removable gate and the second removable gate, respectively;
forming a hardmask layer over the second removable gate;
removing the first removable gate, forming a first cavity between the first pair of spacers;
forming a first work function material between the first pair of spacers;
removing the hardmask layer and the second removable gate, forming a second cavity between the second pair of spacers; and
forming a second work function material, different from the first work function material, in the second cavity.

10. The method according to claim 9, further comprising forming the hardmask layer of polysilicon, amorphous silicon or a combination thereof.

11. The method according to claim 9, further comprising:
forming a first dielectric layer in the first cavity prior to forming the first work function material; and
forming a second dielectric layer in the second cavity prior to forming the second work function material.

12. The method according to claim 9, further comprising:
forming a first metal fill layer over the first work function material; and
forming a second metal fill layer over the second work function material.

13. The method according to claim 9, further comprising:
forming the hardmask layer over the second removable gate by:
forming a hardmask material over the first and second removable gates;
patterning a photoresist over the hardmask material with an opening over the first removable gate; and
removing the hardmask material over the first removable gate through the opening; and
removing the hardmask layer over the second removable gate by:
patterning, after forming the first work function material, a mask with an opening over the second removable gate and the hardmask over the second removable gate; and
removing the hardmask layer through the opening.

14. A semiconductor device comprising:
a substrate;
a p-type gate on the substrate, the p-type gate comprising a first work function layer;
an n-type gate on the substrate, the n-type gate comprising a second work function layer different from the first work function layer; and
spacers on opposite side surfaces of each of the p-type gate and the n-type gate.

15. The semiconductor device according to claim 14, further comprising:
a dielectric layer under the first work function layer and under the second work function layer, for the p-type gate and the n-type gate, respectively.

16. The semiconductor device according to claim 15, further comprising:
a capping layer between the dielectric layer and each of the first and second work function layers, for the p-type gate and the n-type gate, respectively.

17. The semiconductor device according to claim 15, further comprising:
an additional dielectric layer between the dielectric layer and the second work function layer for the n-type gate.

18. The semiconductor device according to claim 17, wherein the dielectric layer comprises hafnium oxide and the additional dielectric layer comprises lanthanum oxide.

19. The semiconductor device according to claim 17, further comprising:
a titanium nitride capping layer on the additional dielectric for the n-type gate.

20. The semiconductor device according to claim 19, further comprising:
a seal layer between the capping layer and the second work function layer for the n-type gate.

21. The semiconductor device according to claim 14, further comprising:
a first metal fill layer on the first work function layer; and
a second metal fill layer on the second work function layer.
